(19) United States
(12) Patent Application Publication
(10) Pub. No.: US 2024/0372040 A1
(43) Pub. Date: Nov. 7, 2024

(54) OPTOELECTRONIC SEMICONDUCTOR CHIP AND METHOD FOR MANUFACTURING THE SAME

(71) Applicant: ams-OSRAM International GmbH, Regensburg (DE)

(72) Inventor: Alexander Pfeuffer, Regensburg (DE)

(21) Appl. No.: 18/567,693

(22) PCT Filed: Jun. 18, 2021
(86) PCT No.: PCT/EP2021/066700

§ 371 Date: Dec. 6, 2023

(51) Int. Cl. H01L 33/40; H01L 33/00; H01L 33/46

(52) U.S. Cl. CPC H01L 33/405; H01L 33/005; H01L 33/46; H01L 2933/0016; H01L 2933/0025

(57) ABSTRACT

In an embodiment an optoelectronic semiconductor chip includes a semiconductor body having an n-doped region, a p-doped region optionally comprising a p-type current distribution layer and an active region arranged between the n-doped region and the p-doped region, a first dielectric layer arranged on the p-doped region, a mirror layer arranged on the first dielectric layer, wherein the first dielectric layer electrically insulates the mirror layer from the p-doped region and the n-doped region, a second dielectric layer arranged on the mirror layer, a metallisation layer arranged on the second dielectric layer, wherein the metallisation layer is electrically isolated from the mirror layer and electrically contacts the p-doped region, and an n-type contact layer deposited on the n-doped region opposite the p-doped region.

### CROSS-REFERENCE TO RELATED APPLICATIONS

This patent application is a national phase filing under section 371 of PCT/EP2021/066700, filed Jun. 18, 2021, which is incorporated herein by reference in its entirety.

### TECHNICAL FIELD

The present application relates to an optoelectronic device and a method for manufacturing the same.

### BACKGROUND

An optoelectronic semiconductor chip and in particular an optoelectronic semiconductor chip with edge lengths of less than 40 μm is provided. Such an optoelectronic semiconductor chip can for example be called an optoelectronic semiconductor μ-chip.

Such μ-chip may in some embodiments be unhoused and may therefore comprise a lot of exposed side surfaces. Due to the exposed side surfaces the chips are more demanding in the encapsulation of corrosion-prone components. In particular reflective metal layers, which my in addition act as electrodes, play a special role. If reflective metal layers are used as electrodes, they can corrode at different rates depending on the applied potential. Highly reflective mirror electrodes made of silver, aluminium or gold are widely used for semiconductor chips. Unfortunately, the highly reflective silver has the property of migrating particularly easily when connected with the p-potential of the μ-chip under humidity and field conditions. By the term “migrating” an electrochemical process can be understood in which metal ions from a first metal layer migrate to a second layer. In Case of a μ-chip, in particular, silver of a silver layer becomes ionic when connected to the p-potential such that ions of the silver layer start migrating to a layer connected to the n-potential and solidify there. Thus, the risk of a short circuit within the μ-chip increases.

Although with a suitable semiconductor structure, the advantages of certain metals that have a very high reflectivity can be combined with electrochemical stabilisation, such electrochemical stabilisation is however complex and very costly.

Some optoelectronic semiconductor components are for example known from the two undisclosed German applications DE 102020124258.1 and DE 102021202026.7.

### SUMMARY

Embodiments provide an optoelectronic semiconductor chip that exhibits improved ageing behaviour and/or which is simple and inexpensive to manufacture.

The optoelectronic semiconductor chip is, for example, a radiation-emitting optoelectronic semiconductor chip. For example, the semiconductor chip may be a light emitting diode (LED) chip or a laser chip. The optoelectronic semiconductor chip may generate light during operation. In particular, it is possible that the optoelectronic semiconductor chip generates light in the spectral range from UV radiation to light in the infrared range, in particular visible light. Alternatively, it is possible that the optoelectronic semiconductor chip is a radiation-detecting semiconductor chip, for example a photodiode.

The optoelectronic semiconductor chip may for example comprise edge lengths of less than 100 μm, or less than 40 μm, and in particular less than 10 μm. The optoelectronic semiconductor chip can thus for example be a μLED (LED for light emitting device, μLED for micro-LED) or a μLED-chip.

According to some embodiments, an optoelectronic semiconductor chip comprises a semiconductor body, the semiconductor body having an n-doped region, a p-doped region optionally comprising a p-type current distribution layer, and an active region arranged between the n-doped region and the p-doped region. The optoelectronic semiconductor chip further comprises a first dielectric layer arranged on the p-doped region and a mirror layer, comprising a metal, arranged on the first dielectric layer. The first dielectric layer thereby electrically insulates the mirror layer at least from the p-doped region and thus from the optional p-type current distribution layer.

A second dielectric layer is further arranged on the mirror layer and a metallisation layer is arranged on the mirror layer. Said metallisation layer is electrically isolated from the mirror layer and electrically contacts the p-doped region and thus the optional p-type current distribution layer. The mirror layer is thus electrically isolated from the optional p-type current distribution layer, from the metallisation layer and in particular from the p-doped region by means of the first and the second dielectric layer. In other words, the mirror layer is in particular electrically isolated from a p-potential which can be connected to the semiconductor chip in operation of the semiconductor chip.

In addition to this, the optoelectronic semiconductor chip comprises an n-type contact layer deposited on the n-doped region opposite the p-doped region, so that the optoelectronic semiconductor chip is in particular of the form of a vertical contactable semiconductor chip which is contactable on two opposing sides of the semiconductor chip.

In some embodiments, the optoelectronic semiconductor chip is thus electrically connectable on two opposing sides of the semiconductor chip by means of the metallisation layer and the n-type contact layer and thus forms a vertical contactable semiconductor chip.

In some embodiments, the mirror layer is electrically connected to the n-doped region and/or to the n-type contact layer and thus the mirror layer is electrically connected to the n-potential, which can be connected to the semiconductor chip in operation of the semiconductor chip. The mirror layer can thus be on an n-potential, however the mirror layer can also not be electrically connected to the n potential and can thus be on a floating potential.

The core of the invention is in particular to reduce migration of the mirror layer by avoiding the mirror layer to be connected to a p-electrode or to the p-potential, which can be connected to the semiconductor chip in operation of the semiconductor chip.

In some embodiments, at least the p-doped region, the active region and optionally a portion of the n-doped region form a first mesa structure and optionally at least a portion of the n-doped region forms a second mesa structure, wherein the second mesa structure laterally protrudes the first mesa structure. In case of a first and a second mesa structure, the first mesa structure is arranged on the second mesa structure in particular in the center of an imaginary top surface of the second mesa structure. A cross sectional area of the first and the second mesa structure can for example each comprise a trapezoidal shape.

In some embodiments, the first dielectric layer is arranged on the p-doped region, in particular on the optional p-type current distribution layer, and on a side surface of the semiconductor body. In some embodiments, the first dielectric layer is arranged on the p-doped region, in particular on the p-type current distribution layer, and on all side surfaces of the semiconductor body. The dielectric layer can thereby cover only a portion of the side surface(s) or the whole side surface(s). In particular, the first dielectric layer is arranged on the p-doped region, in particular on the p-type current distribution layer, and follows a contour of at least one side surface of the first mesa structure. By the term “follows” it can be understood, that the dielectric layer moulds to the contour of the side surface(s) of the semiconductor body and in particular to the side surface(s) of the first mesa structure.

In some embodiments, the mirror layer is arranged on the first dielectric layer on the side surface(s) of the semiconductor body. The mirror layer can thereby cover only a portion of the first dielectric layer on the side surface(s) of the semiconductor body or the whole first dielectric layer on the side surface(s) of the semiconductor body. In particular the mirror layer is arranged on the first dielectric layer on the side surface(s) of the first mesa structure and follows a contour of the first dielectric layer on the side surface(s) of the first mesa structure.

In some embodiments, the second dielectric layer follows the contour of at least one side surface of the semiconductor body and in particular follows a contour of at least one side surface of the first mesa structure. The second dielectric layer can thereby be arranged directly on the side surface(s) of the semiconductor body/first mesa structure, on the on the first dielectric layer on the side surface(s) of the semiconductor body/first mesa structure, or on the mirror layer arranged on the first dielectric layer on the side surface(s) of the semiconductor body/first mesa structure.

The mirror layer can for example comprise or consist of a metal such as silver, gold, and/or aluminium. In particular, the mirror layer can be characterised by the fact that it comprises a high reflectivity to light being generated in the active region of the semiconductor body or to light, the active region of the semiconductor body is sensitive to. The mirror layer can in particular be configured, to reflect light being generated in the active region of the semiconductor body and which exits the active region against a main emission direction of the semiconductor chip into the direction of the main emission direction.

The p-type current distribution layer is optional such that the first dielectric layer can be arranged directly on the p-doped region. The p-type current distribution layer can for example comprise or consist of a conductive material that in addition is at least partially light transmitting for light being generated in the active region of the semiconductor body or to light, the active region of the semiconductor body is sensitive to. In particular, the p-type current distribution layer can comprise or consist of indium tin oxide (ITO).

The first dielectric layer can in some embodiments be formed as a complex Bragg mirror.

In some embodiments, the metallisation layer comprises a contact via at least through the first and the second dielectric layer. By means of the contact via, the metallisation layer on the second dielectric layer can electrically be contacted with the p-doped region and thus with the optional p-type current distribution layer.

In some embodiments, the contact via is located centrally with regard to the semiconductor body or is located on an edge of the semiconductor body. In other words, the access of the metallisation layer to the p-doped region of the semiconductor body can be arranged through the dielectric layers and the mirror layer centrally with regard to the semiconductor body or can be arranged laterally offset the mirror layer through the dielectric layers. In particular the case of the contact via being located on an edge of the semiconductor body can bring area advantages whereas in the case of the contact via being located centrally with regard to the semiconductor body can bring advantages in regard to the homogeneous radiation of light being generated in the active region of the semiconductor body.

The metallisation layer can for example comprise or consist of a conductive material such as platinum, rhodium, titanium, tungsten, gold and/or aluminium. In particular, the metallisation layer can be formed as a comparable thin layer on the second dielectric layer. The choice of the material used for the metallisation layer in particular of the contact via of the metallisation layer can have an impact to the need of the p-type current distribution layer. In case of the metallisation layer comprising no aluminium but for example rhodium, the p-type current distribution layer may be redundant and the metallisation layer in particular the contact via of the metallisation layer can electrically be contacted with the p-doped region directly.

In some embodiments, the metallisation layer can for example comprise or consist of a transparent and conductive material such as transparent conducting films (TCFs). TCFs are thin films of optically transparent and electrically conductive material. While indium tin oxide (ITO) is the most widely used, alternatives include wider-spectrum transparent conductive oxides (TCOs), conductive polymers, metal grids and random metallic networks, carbon nanotubes (CNT), graphene, nanowire meshes and ultra thin metal films. Transparent conductive oxides (TCO) are doped metal oxides for example fabricated with polycrystalline or amorphous microstructures. Typical properties of TCO are a transmittance of incident light greater than 80% as well as electrical conductivities higher than 10³ S/cm for efficient carrier transport.

In some embodiments, the metallisation layer is configured to be reflective or comprises a reflective coating. The metallisation layer can in particular be configured, to reflect light being generated in the active region of the semiconductor body and which exits the active region against a main emission direction of the semiconductor chip and which is not reflected by the mirror layer into the direction of the main emission direction.

In some embodiments, the mirror layer comprises when viewed onto the mirror layer, one of:
a rectangular, polygonal or circular shape with an opening arranged in the center of the semiconductor body; and
a rectangular, polygonal or circular shape with a recess on an edge of the mirror layer.

The mirror layer can thus comprise a ring like shape a rectangle or a polygon with an opening in its center, or a rectangle or polygon with a recess on one of its edges (missing a corner).

In some embodiments, the n-doped region comprises an n-type current distribution layer. In some embodiments, the n-type contact layer comprises or consist of an at least partially transparent conductive material.

A method for manufacturing an optoelectronic semiconductor chip comprises the steps:
providing a semiconductor body on a growth substrate, the semiconductor body comprising
an n-doped region,
a p-doped region optionally comprising a p-type current distribution layer, and
an active region arranged between the n-doped region and the p-doped region;
depositing a first dielectric layer on the p-doped region and a mirror layer, comprising a metal, on the first dielectric layer, such that the first dielectric layer electrically insulates the mirror layer at least from the p-doped region as well as from the optional p-type current distribution layer;
depositing a second dielectric layer on the mirror layer;
depositing a metallisation layer on the second dielectric layer, such that the metallisation layer is electrically isolated from the mirror layer and is electrically contacting the p-doped region and thus the optional p-type current distribution layer; and
depositing an n-type contact layer on the n-doped region opposite the p-doped region.

In some embodiments, the step of providing a semiconductor body comprises generating a first mesa structure, by for example means of an etching process. The first mesa structure may thereby comprises at least the p-doped region and the active region as well as optionally a portion of the n-doped region.

In some embodiments, the method further comprises a step of generating a second mesa structure, by for example means of an etching process. The second mesa structure may thereby comprise at least a portion of the n-doped region and may laterally protrude the first mesa structure. The first mesa structure can for example also be called “shallow mesa” and the second mesa structure can also be called “deep mesa”.

In some embodiments, the step of depositing the first dielectric layer comprises a structuring of the first dielectric layer to provide at least one through hole through the first dielectric layer in an area where the first dielectric layer is in direct contact with the n-doped region and/or in an area where the first dielectric layer is in direct contact with the p-doped region and/or the p-type current distribution layer. The structuring of the first dielectric layer in an area where the first dielectric layer is in direct contact with the n-doped region can for example serve to provide a through hole through the first dielectric layer to be able to connect the mirror layer to the n-doped region electrically. The structuring of the first dielectric layer in an area where the first dielectric layer is in direct contact with the p-doped region and/or the p-type current distribution layer can however serve to provide a through hole through the first dielectric layer to be able to electrically connect the metallisation layer with the p-doped region and/or the p-type current distribution layer. The step of structuring can for example comprise a photolithographic process and/or an etching process, in particular a dielectric wet etching process.

In some embodiments, the step of depositing the mirror layer comprises a step of electrically connecting the mirror layer and the n-doped region. The mirror layer can therefore be deposited on the structured dielectric layer such that a though hole through the first dielectric layer in an area where the first dielectric layer is in direct contact with the n-doped region is filled with the material of the mirror layer and thus electrically contacts the n-doped region.

In some embodiments, the step of depositing the metallisation layer comprises a step of etching a through hole through the second dielectric layer and/or the first dielectric layer and/or the p-type current distribution layer. Due to the step of etching a through hole through the second dielectric layer and/or the first dielectric layer and/or the p-type current distribution layer a contact via of the metallisation layer can be generated through the second dielectric layer and/or the first dielectric layer and/or the p-type current distribution layer to electrically contact the p-doped region and/or the p-type current distribution layer.

The step of depositing the metallisation layer can comprise a targeted deposition of the metallisation layer or an areal deposition of the metallisation layer and a subsequent structuring of the areal-deposited metallisation layer.

In some embodiments, the method further comprises a step of depositing a release layer on the metallisation layer. The release layer can in particular be a temporary layer, which can be removed easily by means of for example dissolving.

In some embodiments, the step of depositing the release layer comprises generating a through hole through the release layer in an area of the release layer, where the release layer is in direct contact with the first and/or second dielectric layer. The through hole through the release layer can in particular serve to provide a later support structure for the semiconductor chip.

In some embodiments, the method further comprises a step of gluing or solder bonding the release layer on a carrier, such that the through hole is filled with the gluing or solder material. In particular, the existing intermediate product is encapsulated in the gluing or solder material and can thus be re-bonded. The gluing or solder material in the trough hole can in particular form a later support structure for the semiconductor chip.

In some embodiments, the method further comprises a step of removing the growth substrate and/or a step of removing a portion of the n-doted region until at least the release layer is partially exposed. By this, the release layer is at least partially exposed to allow removing the release layer by for example dissolving. The step of removing a portion of the n-doted region can for example comprise a step of thinning, grinding, polishing, chemical-mechanical polishing (CMP) and/or etching the n-doted region.

### BRIEF DESCRIPTION OF THE DRAWINGS

In the following, embodiments of the invention will be explained in more detail with reference to the accompanying drawings.

FIG. 1 to FIG. 4 show steps of a method for manufacturing an optoelectronic semiconductor chip according to some aspects of the invention;

FIG. 5A to FIG. 5E show variants of a further step of a method for manufacturing an optoelectronic semiconductor chip according to some aspects of the invention;

FIG. 6 and FIG. 7 show further steps of a method for manufacturing an optoelectronic semiconductor chip according to some aspects of the invention;

FIG. 8A to FIG. 8C show variants of a further step of a method for manufacturing an optoelectronic semiconductor chip according to some aspects of the invention,

FIG. 9 to FIG. 16 show further steps of a method for manufacturing an optoelectronic semiconductor chip according to some aspects of the invention; and

FIG. 17 shows a further step of a method for manufacturing an optoelectronic semiconductor chip according to some aspects of the invention as well as an optoelectronic semiconductor chip according to some aspects of the invention.

### DETAILED DESCRIPTION OF ILLUSTRATIVE EMBODIMENTS

The present disclosure will now be described more fully hereinafter with reference to the accompanying drawings, in which exemplary embodiments of the disclosure are shown. The disclosure may, however, be embodied in many different forms and should not be construed as limited to the embodiments set forth herein; rather, these embodiments are provided for thoroughness and completeness. Like reference characters refer to like elements throughout the description. The drawings are not necessarily to scale and certain features may be exaggerated in order to better illustrate and explain the exemplary embodiments of the present disclosure.

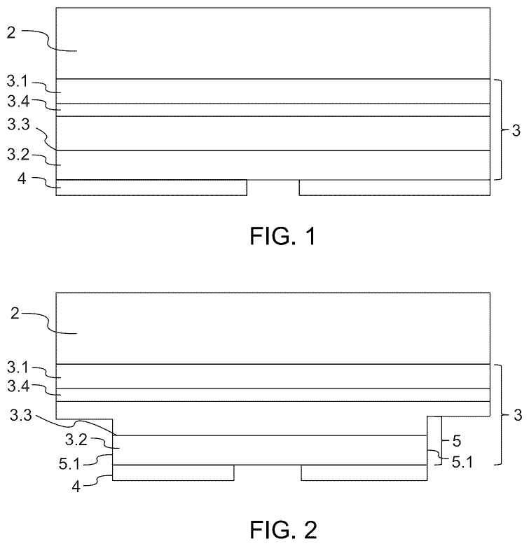

FIG. 1 shows the first steps of a method for manufacturing an optoelectronic semiconductor chip 1. A semiconductor body 3 is therefore provided on a growth substrate 2, wherein the semiconductor body 3 comprises an n-doped region 3.1, a p-doped region 3.2, and an active region 3.3 arranged between the n-doped region 3.1 and the p-doped region 3.2. The n-doped region 3.1 further comprises an n-type current distribution layer 3.4 located within the n-doped region 3.1. The semiconductor body 3 can thus form a semiconductor layer stack of the semiconductor material, such as GaN, in form of for example a support and growth wafer. In the figure and the following figures only a portion, forming a later semiconductor chip, of the growth substrate 2 and the semiconductor layer stack is exemplarily shown. However, the growth substrate 2 and the semiconductor layer stack as well as following layers and components may be continued to the left and right of the portion shown.

In a further step, a p-type current distribution layer 4 is deposited on the p-doped region 3.2. The p-type current distribution layer 4 particularly comprises or consist of a conductive material, which is in addition at least partially transmissive for light. As shown in the figure, the p-type current distribution layer 4 may for example be structured and comprise an opening that can be centred or off centre with regard to the semiconductor body 3.

FIG. 2 shows a further step of the method, in which a first mesa structure 5 is generated from the semiconductor body 3. By use of for example an etching process, in particular a dry etching process, the first mesa structure 5 is generated such that it comprises at least the p-doped region 3.2, the active region 3.3 and a portion of the n-doped region 3.1.

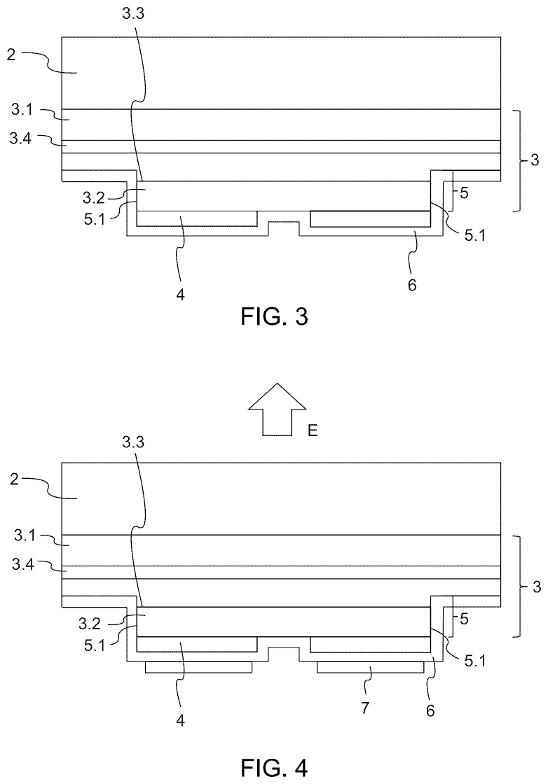

On top of the generated contour, a first dielectric layer 6 is deposited as shown in FIG. 3. The first dielectric layer 6 is arranged on the p-type current distribution layer 4, on the p-doped region 3.2, on portions of the n-doped region 3.1, as well as on side surfaces 5.1 of the first mesa structure 5.

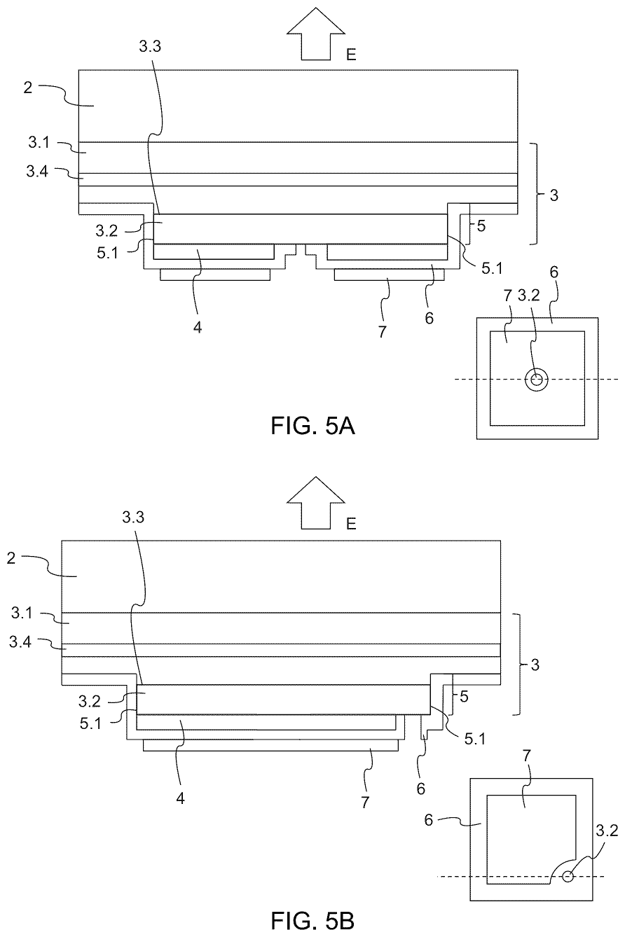

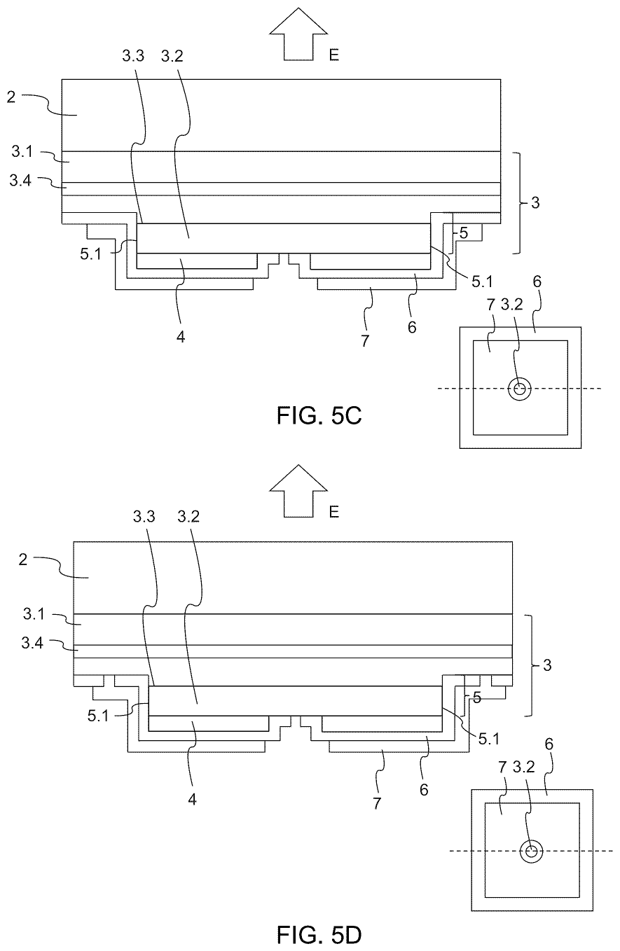

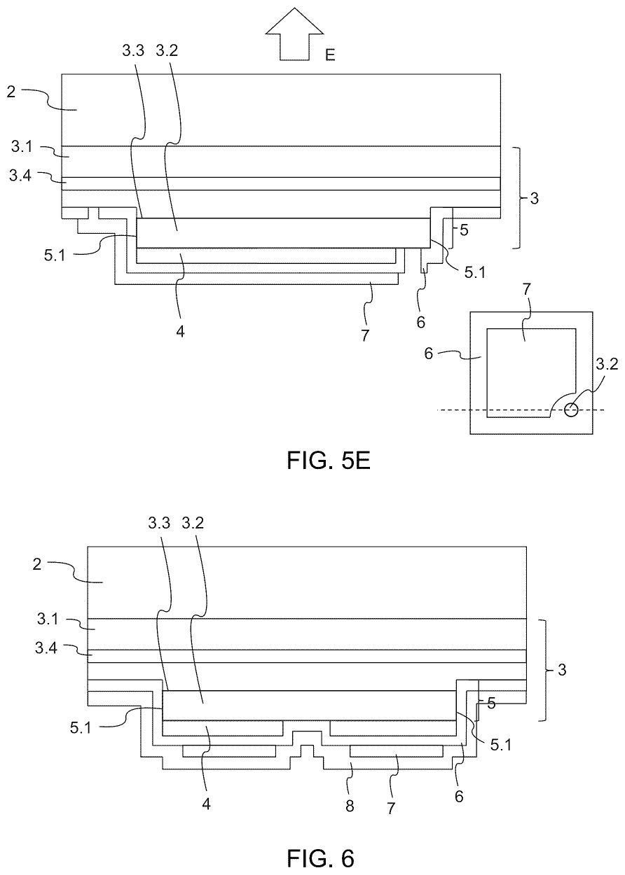

In a further step, as shown in FIG. 4, a mirror layer 7 is deposited on the first dielectric layer 6. The mirror layer 7 can for example comprise or consists of a metal such as for example silver, aluminium and/or gold, and can in particular be highly reflective. As shown in the figure the mirror layer 7 can be arranged on the first dielectric layer 6 only in regions opposite the p-doped region 3.2 but can also, as shown in the following FIGS. 5A to 5E, be arranged in other regions on the first dielectric layer 6.

The first dielectric layer 6 is however in any case arranged between the mirror layer 7 and the p-type current distribution layer 4 and/or the p-doped region 3.2 such that it electrically insulates the mirror layer 7 from the p-type current distribution layer 4 and the p-doped region 3.2.

FIG. 5A shows a first variant of the mirror layer 7 being arranged on the first dielectric layer 6 in a cross sectional view as well as in a top view. The mirror layer 7 is of the form of a rectangle with an opening in its centre, when viewed onto the mirror layer 7. Below the opening of the mirror layer 7, the first dielectric layer 6 is structured/comprises a through hole, to be able to electrically connect a later metallisation layer with the p-doped region 3.2 and/or the p-type current distribution layer 4. Such an arrangement of the opening in the centre of the mirror layer can bring advantages with regard to a homogeneous radiation of light being generated in the active region 3.3 of the semiconductor body 3.

FIG. 5B shows a second variant of the mirror layer 7 in a cross sectional view as well as in a top view, wherein the mirror layer 7 is of the form of a rectangle with a recess at one of its corners. With other words, one corner of the mirror layer 7 is missing. Below the recess of the mirror layer 7, the first dielectric layer 6 is structured/comprises a through hole, to be able to electrically connect a later metallisation layer with the p-doped region 3.2 and/or the p-type current distribution layer 4. Such an arrangement of the recess can in particular bring area advantages for the semiconductor chip, as a contacting of the p-doped region 3.2 can be from an edge of the semiconductor chip and can thus be less space consuming.

A further development of the mirror layer 7 shown in FIG. 5A is shown in FIG. 5C. The mirror layer 7 thereby not only covers the first dielectric layer 6 in an area opposite to the p-doped region 3.2 but also along the side surfaces 5.1 of the first mesa structure 5. The mirror layer 7 thus encloses a backside and side surfaces of the first mesa structure 5 to ensure that light being generated in the active region 3.3 of the semiconductor body 3, which exits the active region 3.3 in any direction but not in the main emission direction E of the semiconductor chip, is reflected by the mirror layer 7 into the direction of the main emission direction E. Therefore, the efficiency of the semiconductor chip can be improved as more light, generated in the active region 3.3 of the semiconductor body 3, can be guided and thus emitted from the semiconductor chip into the direction of the main emission direction E.

As shown in FIG. 5D the mirror layer 7 is in addition to the mirror layer 7 of FIG. 5C electrically connected to the n-doped region 3.1. The first dielectric layer 6 therefore comprises the shown at least two through holes in an area where the first dielectric layer 6 is in direct contact with the n-doped region 3.1. By this, the mirror layer 7 can be electrically connected to the n-potential, which can be connected to the semiconductor chip in operation of the semiconductor chip. The mirror layer 7 can thus be connected to an n-potential and is not floating.

FIG. 5E shows in contrast to the mirror layer 7 of FIG. 5D a mirror layer 7, which comprises a recess at one of its corners and not an opening in its centre. Thereby the area advantages can be combined with the increase of the efficiency of the semiconductor chip as well as with the advantage of the mirror layer being connected to an n-potential.

FIG. 6 shows a further step of the method for manufacturing an optoelectronic semiconductor chip. A second dielectric layer 8 is thereby deposited on the mirror layer 7. The second dielectric layer 8 is arranged on the mirror layer 7, as well as on the first dielectric layer 6 and follows the contour of the two layers. Hence, the second dielectric layer 8 also follows the contour of the side surfaces 5.1 of the first mesa structure 5. The second dielectric layer 8 is in particular of a different material as the first dielectric layer 6 but can in some embodiments be of the same material as the first dielectric layer 6 as well.

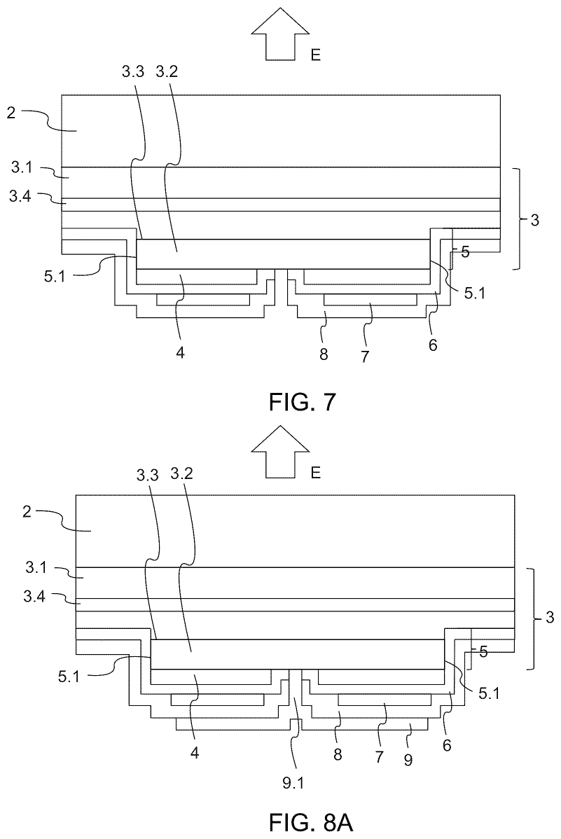

The second dielectric layer 8, and if not already done in a previous step the first dielectric layer 6 as well as the p-type current distribution layer 4, is/are structured as shown in FIG. 7 to provide a through hole through the second dielectric layer 8 and/or the first dielectric layer 6 and/or the p-type current distribution layer 4, to be able to connect a later metallisation layer by means of a contact via with the p-doped region 3.2 and/or the p-type current distribution layer 4.

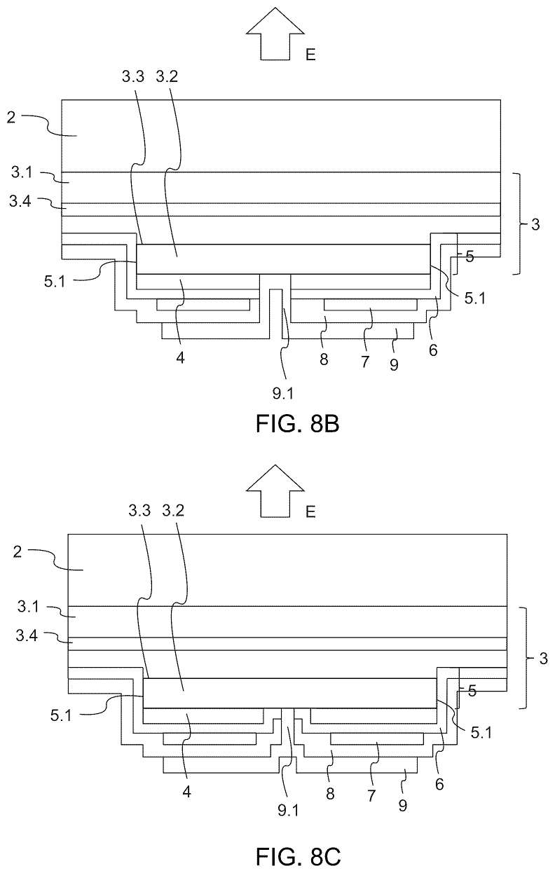

The metallisation layer 9 can be deposited onto the second dielectric layer 8 according to any one of the variants as shown in FIGS. 8A to 8C. According to FIG. 8A the metallisation layer 9 is deposited onto the second dielectric layer 8 only in regions where a later p-contact/p-pad shall be provided in the semiconductor chip. The metallisation layer 9 comprises a contact via 9.1 through the second dielectric layer 8 and the first dielectric layer 6, not contacting the p-type current distribution layer 4. However the metallisation layer 9 can also be deposited on the whole area of the second dielectric layer 8 and can in a subsequent step be structured to achieve a desired shape. A current introduced via the metallisation layer 9 spreads thereby directly into the p-region 3.2. This can in particular be advantageous as material interactions can occur between the metallisation layer 9 and the p-type current distribution layer 4, which are prevented by the metal layer directly contacting the p-region and not introducing the current via the p-type current distribution layer 4. In case of for example the p-type current distribution layer 4 comprising a material like ITO, and the metallisation layer 9 and thus the contact via 9.1 comprising a material like Titanium (Ti), material interactions between these two materials can cause unwanted effects.

FIG. 8B shows a variant of the metallisation layer 9 comprising a contact via 9.1 through the second dielectric layer 8, the first dielectric layer 6 and the p-type current distribution layer 4, the contact via 9.1 contacting the p-current distribution layer 4 along inner side surfaces 4.1 of the p-current distribution layer 4. The advantage of such an arrangement is that a current introduced via the metallisation layer 9 spreads into the p-type current distribution layer 4 in an improved manner and no or only minimal current is spread directly into the p-region 3.2.

In this specific example shown in FIG. 8B the contact via 9.1 comprises an indent along its direction of propagation, which can be caused due to the process of depositing the metallisation layer 9 onto the second dielectric layer 8, as a process of depositing can comprise a growing of the metallisation layer 9 on the existing contour. Therefore, the through hole through the second dielectric layer 8, the first dielectric layer 6 and the p-type current distribution layer 4 may not be filled completely by the material of the metallisation layer 9.

FIG. 8C shows a further variant of the metallisation layer 9. In contrast to the metallisation layer shown in FIG. 8A the contact via 9.1 of the metallisation layer 9 contacts the p-type current distribution layer 4, but not the p-doped region 3.2, as the p-type current distribution layer 4 is formed as a continuous layer and is not structured or does not comprise a through hole. A current introduced via the metallisation layer 9 thus spreads directly into the p-type current distribution layer 4.

The metallisation layer 9 may comprise a reflective material or may in addition comprise a reflective coating at least on its surface directed towards the semiconductor body 3. Thus, light being generated in the active region 3.3 of the semiconductor body 3, which exits the active region 3.3 against a main emission direction E of the semiconductor chip and which is not reflected by the mirror layer 7 can be reflected from the metallisation layer 9 into the direction of the main emission direction E.

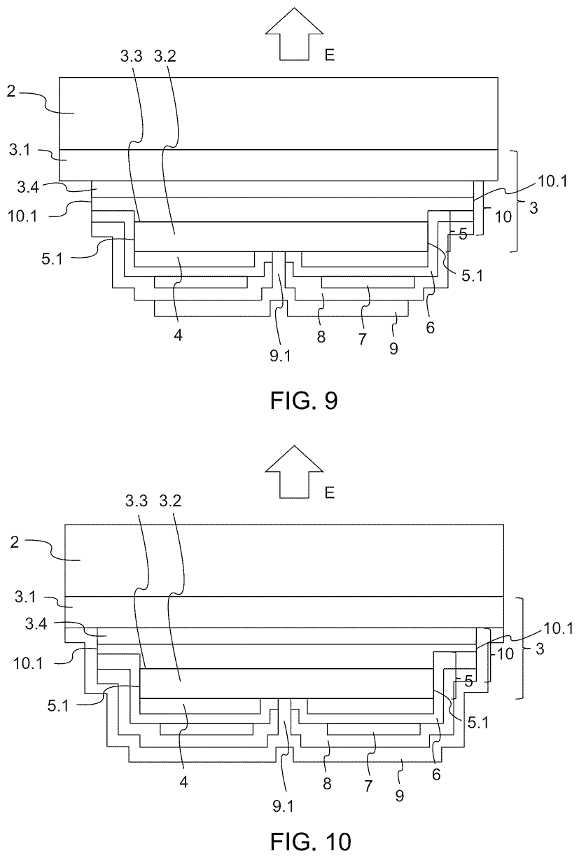

As shown in FIG. 9 the method further comprises a step of generating a second mesa structure 10. By use of for example an etching process, in particular dry etching process, the second mesa structure 10 is generated such that it comprises a portion of the n-doped region 3.1 as well as a portion of the first and second dielectric layer 6, 8, and such that the second mesa structure 10 laterally protrudes the first mesa structure 5.

The order of the step of generating a second mesa structure 10 and the step of depositing the metallisation layer 9 can also be switched as shown in FIG. 10. There the second mesa structure 10 was generated before the metallisation layer 9 has been deposited onto the second dielectric layer 8 as well as on side surfaces 10.1 of the second mesa structure 10. In a subsequent step, the metallisation layer 9 is however to be structured, to achieve a desired shape of the metallisation layer 9 on the one hand and to avoid an electrical contact between the metallisation layer 9 and the n-doped region 3.1.

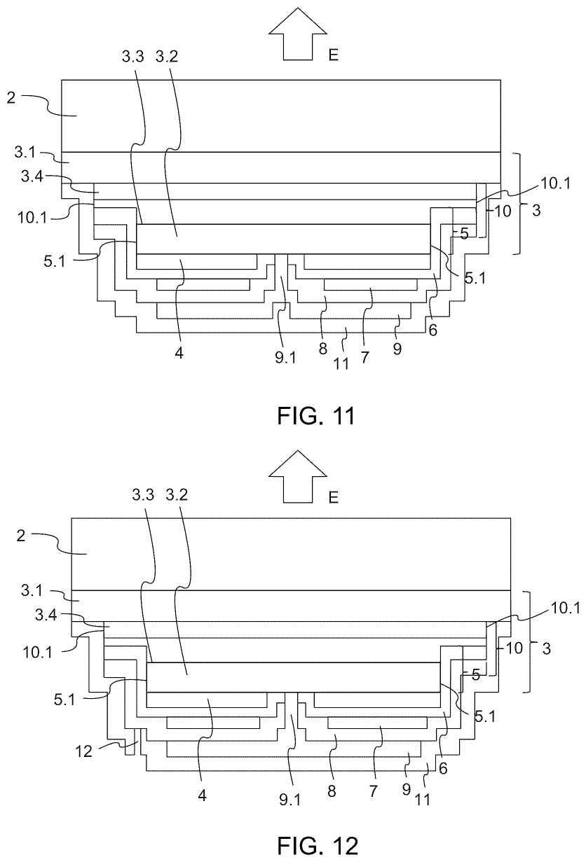

FIG. 11 shows a further step of the method in which a release layer 11 is deposited onto the metallisation layer 9, the second dielectric layer 8 and the side surfaces 10.1 of the second mesa structure 10. The release layer 11 can in particular be a temporary layer, which can be removed easily by means of for example dissolving. As shown in the figure the release layer covers the whole surface opposite the growth substrate 2 as a preparation for a subsequent gluing/solder bonding step.

After the release layer 11 is deposited on the metallisation layer 9, a through hole 12 is generated through the release layer 11 in an area of the release layer 11, where the release layer 11 is in direct contact with the second dielectric layer 8 as shown in FIG. 12. The through hole 12 through the release layer 11 serves to provide a later support structure for the semiconductor chip.

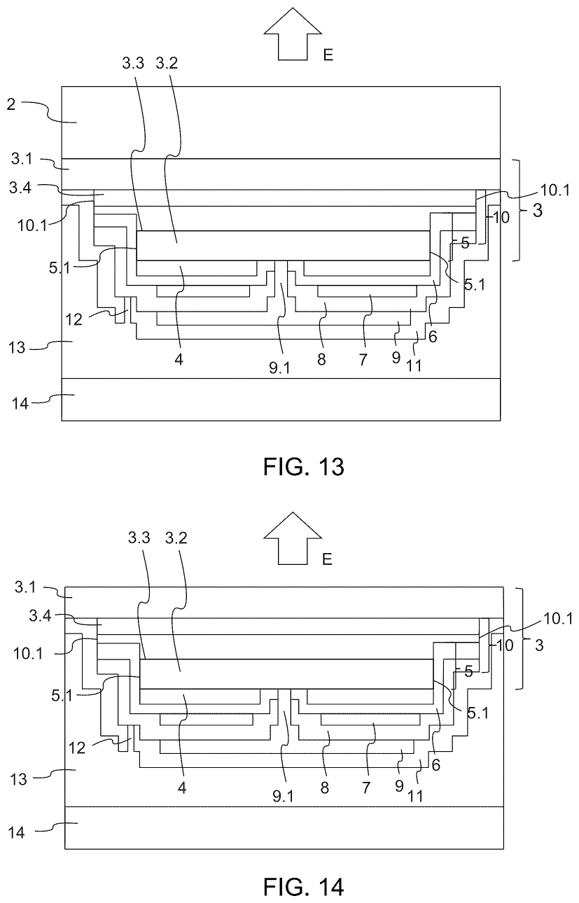

By means of a gluing/solder bonding step the existing intermediate product/waver is encapsulated in a gluing/solder material 13 on a carrier 14. Thereby the through hole 12 is also filled with the gluing/solder material 13, as shown in FIG. 13, to form a later support structure for the semiconductor chip. The resulting intermediate product can then be flipped and the growth substrate 2 can be removed as shown in FIG. 14.

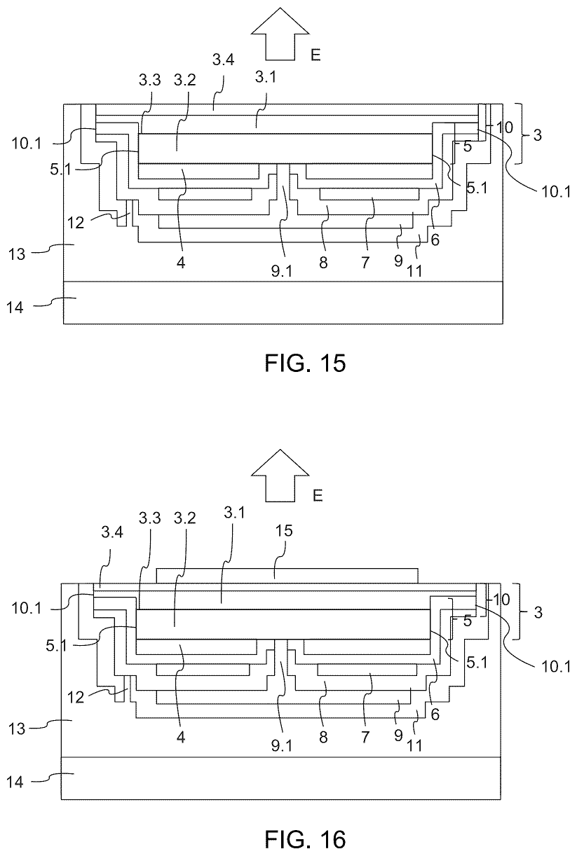

In a further step, as shown in FIG. 15, a portion of the n-doped region 3.1 is removed until the release layer 11 is at least partially exposed. The step of removing the n-doped region 3.1 can for example comprise a step of thinning, grinding, polishing and/or etching the n-doped region 3.1.

FIG. 16 shows step of depositing an n-type contact layer 15 on the n-doped region 3.1 opposite the p-doped region 3.2. The n-type contact layer 15 can in particular serve as an n-contact/n-pad of the semiconductor chip.

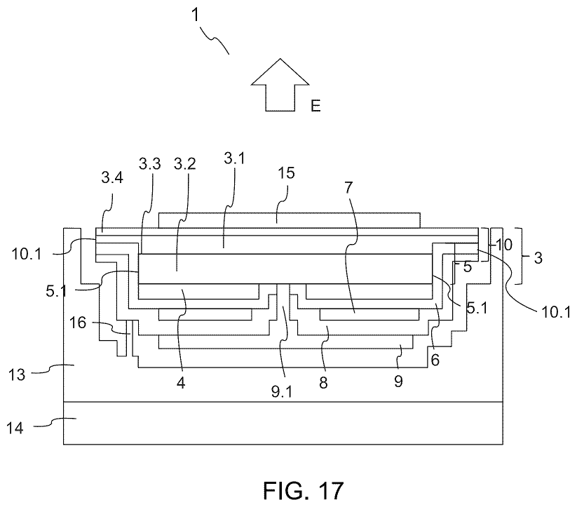

The release layer 11 is then, as shown in FIG. 17, for example this solved, such that the resulting semiconductor chip 1 is only connected to the support structure 16. The semiconductor chip 1 can then be removed from the wafer by for example a stamping process or any other process known in the art.

The resulting semiconductor chip 1 is characterised in particular by the fact that the mirror layer 7 is at least not electrically connected with the p-doped region 3.2, the p-type current distribution layer 4 and the metallisation layer 9. Therefore, the ageing behaviour of the semiconductor chip one is improved.

1.-24. (canceled)

25. An optoelectronic semiconductor chip comprising:
a semiconductor body comprising:
an n-doped region;
a p-doped region optionally comprising a p-type current distribution layer; and
an active region arranged between the n-doped region and the p-doped region;
a first dielectric layer arranged on the p-doped region;
a mirror layer comprising a metal and arranged on the first dielectric layer, wherein the first dielectric layer electrically insulates the mirror layer from the p-doped region and the n-doped region;
a second dielectric layer arranged on the mirror layer;
a metallisation layer arranged on the second dielectric layer, wherein the metallisation layer is electrically isolated from the mirror layer and electrically contacts the p-doped region; and
an n-type contact layer deposited on the n-doped region opposite the p-doped region.

26. The optoelectronic semiconductor chip according to claim 25, wherein at least the p-doped region and the active region form a first mesa structure and optionally at least a portion of the n-doped region forms a second mesa structure, and wherein the second mesa structure laterally protrudes the first mesa structure.

27. The optoelectronic semiconductor chip according to claim 26, wherein the first dielectric layer is arranged on a side surface of the semiconductor body and follows a side surface of the first mesa structure.

28. The optoelectronic semiconductor chip according to claim 27, wherein the mirror layer is arranged on the first dielectric layer on the side surface of the semiconductor body.

29. The optoelectronic semiconductor chip according to claim 26, wherein the second dielectric layer follows a side surface of the semiconductor body and follows a side surface of the first mesa structure.

30. The optoelectronic semiconductor chip according to claim 25, wherein the optoelectronic semiconductor chip is electrically connectable on two opposing sides of the semiconductor chip by the metallisation layer and the n-type contact layer.

31. The optoelectronic semiconductor chip according to claim 25, wherein the metallisation layer comprises a contact via at least through the first and second dielectric layers.

32. The optoelectronic semiconductor chip according to claim 31, wherein the contact via is located centrally with regard to the semiconductor body or is located on an edge of the semiconductor body.

33. The optoelectronic semiconductor chip according to claim 25, wherein the metallisation layer is reflective or comprises a reflective coating.

34. The optoelectronic semiconductor chip according to claim 25, wherein, when viewed on the mirror layer, the mirror layer comprises at least one of a rectangular, polygonal or circular shape with an opening arranged in the center of the semiconductor body, or a rectangular, polygonal or circular shape with a recess on an edge of the mirror layer.

35. The optoelectronic semiconductor chip according to claim 25, wherein the n-doped region comprises an n-type current distribution layer.

36. The optoelectronic semiconductor chip according to claim 25, wherein the n-type contact layer comprises an at least partially transparent material.

37. A method for manufacturing an optoelectronic semiconductor chip, the method comprising:
providing a semiconductor body on a growth substrate, the semiconductor body comprising an n-doped region, a p-doped region optionally comprising a p-type current distribution layer, and an active region arranged between the n-doped region and the p-doped region;
depositing a first dielectric layer on the p-doped region and a mirror layer, comprising a metal, on the first dielectric layer such that the first dielectric layer electrically insulates the mirror layer at least from the p-doped region;
depositing a second dielectric layer on the mirror layer;
depositing a metallisation layer on the second dielectric layer such that the metallisation layer is electrically isolated from the mirror layer and electrically contacts the p-doped region;
depositing a release layer on the metallisation layer, wherein depositing the release layer comprises generating a through hole through the release layer in an area of the release layer, and wherein the release layer is in direct contact with the first dielectric layer and/or the second dielectric layer;
gluing or solder bonding the release layer on a carrier such that the through hole is filled with a gluing material or a solder material;
depositing an n-type contact layer on the n-doped region opposite the p-doped region; and
removing the release layer.

38. The method according to claim 37, wherein providing the semiconductor body comprises generating a first mesa structure, and wherein the first mesa structure comprises at least the p-doped region and the active region.

39. The method according to claim 38, further comprising generating a second mesa structure, wherein the second mesa structure comprises at least a portion of the n-doped region and laterally protrudes the first mesa structure.

40. The method according to claim 37, wherein depositing the first dielectric layer comprises a structuring of the first dielectric layer to provide at least one through hole through the first dielectric layer in an area where the first dielectric layer is in direct contact with the n-doped region and/or in an area where the first dielectric layer is in direct contact with the p-doped region.

41. The method according to claim 37, wherein depositing the mirror layer comprises electrically connecting the mirror layer and the n-doped region.

42. The method according to claim 37, wherein depositing the metallisation layer comprises etching the through hole through the second dielectric layer and/or the first dielectric layer and/or the p-type current distribution layer.

43. The method according to claim 37, wherein depositing the metallisation layer comprises structuring of the metallisation layer.

44. The method according to claim 37, further comprising removing the growth substrate and/or removing a portion of the n-doped region until at least the release layer is partially exposed.
